(19) United States
(12) Patent Application Publication
(10) Pub. No.: US 2012/0194101 A1
(43) Pub. Date: Aug. 2, 2012

(54) ELECTRICAL CONNECTION AND METHOD FOR MAKING THE SAME

(76) Inventors: Karl M. Kropp, St. Paul, MN (US); Earl J. Hayes, South Lyon, MI (US)

(21) Appl. No.: 13/497,192

(22) PCT Filed: Sep. 23, 2010
(86) PCT No.: PCT/US10/49959

§ 371 Date: Mar. 20, 2012

Related U.S. Application Data
(60) Provisional application No. 61/245,040, filed on Sep. 23, 2009.

(51) Int. Cl. H05B 37/00; H01R 43/00; H05K 1/16

(52) U.S. Cl. 315/312; 174/260; 29/825

(57) ABSTRACT

Electrical component assembly (30) comprising a first electrical component (32) comprising an electrical connection protrusion (34) (e.g., a solder bump) made of a first metal solder composition having a first melting point, and a second electrical component (36) comprising an electrical contact (38). A second metal solder composition (40) having a second melting point is formed or otherwise disposed so as to function as an electrical connection between at least a portion of the electrical connection protrusion (34) and the electrical contact (38) of the second electrical component (36). The second melting point is lower than the first melting point, and there is a distinct interface of demarcation between the electrical connection protrusion (34) and the second metal solder composition (40).

### BACKGROUND

Techniques for electrically connecting electrical components are known in the art, and include various forms and methods of making solder joints. There is a continuing need for improvements in such solder joints, including more cost effective ways to make solder joints.

### SUMMARY

In accordance with one aspect of the present invention, an electrical component assembly is provided that comprises a first electrical component comprising an electrical connection protrusion (e.g., a solder bump) made of a first metal solder composition having a first melting point, and a second electrical component comprising an electrical contact. A second metal solder composition having a second melting point is formed or otherwise disposed so as to function as an electrical connection between at least a portion of the electrical connection protrusion and the electrical contact of the second electrical component. The second melting point is lower than the first melting point, and there is a distinct interface of demarcation between the electrical connection protrusion and the second metal solder composition. As used herein, there is a distinct interface of demarcation between the electrical connection protrusion and the second metal solder composition when the second metal solder composition is melted while in contact with the electrical connection protrusion, and the electrical connection protrusion does not melt, resulting in no visual evidence of mixing between the electrical connection protrusion and the second metal solder composition, when a cross-section therethrough is viewed using a scanning electron microscope at 75×.

The electrical connection protrusion can have an exposed outer surface, a height in a range from 0.25 mm to 2.5 mm (in some embodiments, 0.25 mm to 2 mm, 0.25 mm to 1.5 mm, 0.25 mm to 1 mm, or even 0.25 mm to 0.5 mm), and a longest dimension (e.g., diameter) perpendicular to the height in a range from 0.5 mm to 5 mm (in some embodiments, 1 mm to 4 mm). In addition, the electrical contact of the second electrical component can be spaced from or in direct contact with a portion of an outer surface of the electrical connection protrusion. A remaining outer surface of the electrical connection protrusion may also be left exposed.

Exemplary electrical components can include circuit boards (e.g., printed circuit boards), electrical cables (e.g., flexible flat electrical cables), and buss bars.

In another aspect of the present invention, a flexible lighting assembly is provided that comprises any electrical component assembly according to the present invention.

In an additional aspect of the present invention, a method of making an electrical component assembly is provided that comprises providing a first electrical component comprising an electrical contact; forming an electrical connection protrusion in electrical communication with the electrical contact of the first electrical component, with the electrical connection protrusion being made of a first metal solder composition having a first melting point; providing a second electrical component comprising an electrical contact; placing the electrical contact of the second electrical component and the electrical connection protrusion proximate to (e.g., spaced apart or so as to be in direct contact with) each other; disposing a second metal solder composition between at least a portion of the electrical connection protrusion and the electrical contact of the second electrical component, with the second metal solder composition having a second melting point that is lower than the first melting point; melting the second metal solder composition at a temperature below the first melting point so as to provide molten second metal solder composition between at least a portion of the electrical connection protrusion and the electrical contact of the second electrical component; and solidifying the molten second metal solder composition so as to form an electrical connection between at least a portion of the electrical connection protrusion and the electrical contact of the second electrical component. The molten second metal solder composition can be solidified such that there is a distinct interface of demarcation between the electrical connection protrusion and the second metal solder composition.

The present disclosure provides a technique for electrically connecting, for example, a capacitive sensor switch or other electronic printed circuit board modules (e.g., such as a node driver or electro-mechanical switch) to a flat flexible electrical cable.

Advantages of embodiments of electrical connection techniques described herein can include the ability to control, via the height of the electrical connection protrusion, the distances between the electrical components being connected. Further, embodiments of electrical connection techniques described herein can facilitate control where solder flows when melted (e.g., during reflow) to form an electrical connection between electrical components.

The electrical connection techniques described herein can also allow for one electrical component (e.g., the printed circuit board) to be positioned relative to another electrical component (e.g., the exposed conductor of an electrical cable), before being electrically connected together, such that their relative position is maintained both vertically and horizontally during the solder melting portion (e.g., solder reflow process) of the electrical connecting process.

Another advantage of embodiments of electrical component assemblies described herein can be a lower internal electrical resistance as compared to the use of conventional electrical connection protrusions such as metal rivets. Advantages of at least some embodiments of electrical component assemblies described herein can also include being able to combine electrical components using conventional manufacturing process with minimal tooling changes.

Embodiments of electrical component assemblies, and electrical component assemblies made as described herein, can useful for, and may be comprised in, task lighting and vehicles (e.g., automobiles, trucks, airplanes, trains, etc.). An exemplary vehicle electrical assembly is a brake center light (also sometimes referred to as a center high mount stop light (CHMSL)).

### BRIEF DESCRIPTION OF THE DRAWING

FIG. 1A is a top view of an exemplary flexible lighting assembly according to the present invention.

FIG. 1B is a cutaway side view of part of the exemplary flexible lighting assembly shown in FIG. 1A.

FIG. 1C is a cross-sectional end view of the flat flexible electrical cable shown in FIGS. 1A and 1B.

FIG. 1D is an electrical diagram of a lighting assembly.

FIG. 2 is a cross-sectional side view of an exemplary electrical component assembly according to the present invention.

FIG. 3 is a cross-sectional side view of one embodiment of an electrical connection solder bump protrusion of a first electrical component according to the present invention.

FIG. 4 is a cross-sectional side view of another embodiment of an electrical connection solder bump protrusion of a first electrical component according to the present invention.

FIG. 5 is a backscattered digital electron image of a polished cross-section of an exemplary electrical connection like that shown in FIG. 2.

### DETAILED DESCRIPTION

Exemplary electrical components that can be electrically connected via an electrical connection protrusion(s) (e.g., a solder bump(s)) as described herein include circuit boards and flat flexible electrical cables, wherein, for example, a circuit board having an electrical connection protrusion made of a first metal composition having a first melting point and an exposed outer surface, and a flat flexible electrical cable with an electrical contact are placed so that the electrical contact is in proximity to (e.g., direct contact with) a portion of the outer exposed surface of the electrical connection protrusion, leaving a remaining outer exposed surface of the electrical connection protrusion, and wherein a second solder composition having a second melting point, lower than the first melting point is heated to provide a melt that is disposed around at least a portion of the remaining exposed outer surface of the electrical connection protrusion without melting the first metal composition, and then the melt disposed around the mentioned portion of the remaining exposed outer surface of the electrical connection protrusion is cooled.

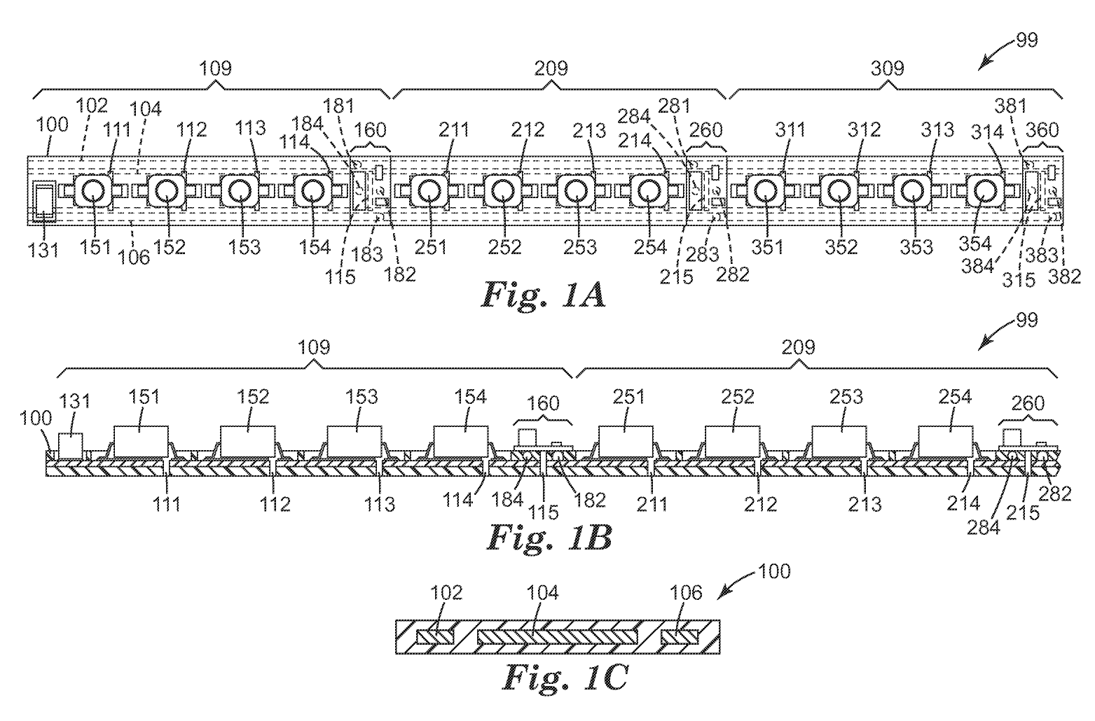

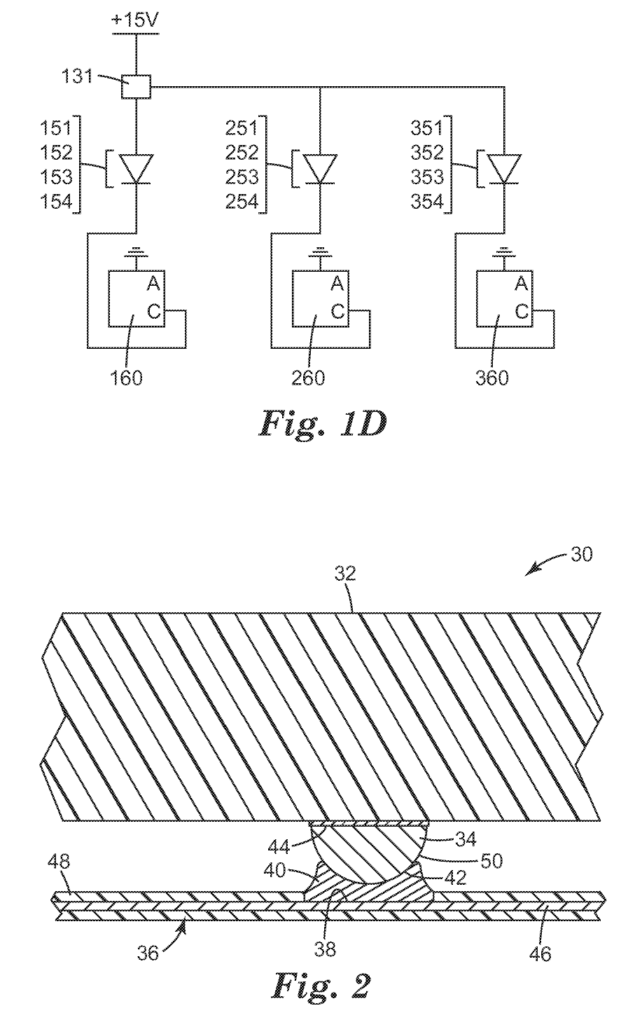

Referring to FIGS. 1A, 1B, and 1C, exemplary lighting assembly 99 has electrical cable 100 having electrical conductors 102, 104, 106, solder bumps 181, 182, 183, 184, 281, 282, 283, 284, 381, 382, 383, 384, and cutouts 111, 112, 113, 114, 115, 211, 212, 213, 214, 215, 311, 312, 313, 314, 315 to provide electrical circuit paths, and first, second, and optional third electrical groups 109, 209, 309, respectively, electrically connected in parallel to electrical cable 100. First electrical group 109 has (zero ohm) electrical resistor or link 131, light emitting diode 151, optional light emitting diodes 152, 153, 154, and control circuit 160 electrically connected sequentially in series. Second electrical group 209 has light emitting diode 251, optional light emitting diodes 252, 253, 254, and control circuit 260 electrically connected sequentially in series. Third electrical group 309 has light emitting diode 351, optional light emitting diodes 352, 353, 354, and control circuit 360 electrically connected sequentially in series. Although not shown, as is known in the art, optionally a rectifier can be used to protect or ensure power bias.

Further, FIG. 1D shows the electrical circuitry for exemplary lighting assembly 99, which includes a 15 V power source (as shown), Schottky diode or zero ohm resistor 131, and light emitting diode 151, optional light emitting diodes 152, 153, 154, and control circuit 160 electrically connected sequentially in series, and in turn in parallel to light emitting diode 251, optional light emitting diodes 252, 253, 254, and control circuit 260 electrically connected sequentially in series, and in turn in parallel to light emitting diode 351, optional light emitting diodes 352, 353, 354, and control circuit 360 electrically connected sequentially in series. Further “C” designates the LED current sync pin, and “A” designates the LED bias protection pin. The respective light emitting diode is connected to the cathode of the respective control circuit. Although not wanting to be bound by theory, it is believed it is advantageous to connect to the LED current sync pin (C) of the control circuit and use an external diode (131) for bias protection rather than use the LED bias protection pin (A). Further, although not wanting to be bound by theory, it is believed that this arrangement prevents temperature feedback from the LED to the control circuit and prevents affecting the ambient temperature measuring monitor within the control circuit.

Referring to FIG. 2, an exemplary electrical component assembly 30 according to the present invention comprises a first electrical component 32 (e.g., a printed circuit board) comprising an electrical connection protrusion 34 (e.g., a solder bump) made of a first metal solder composition having a first melting point, and a second electrical component 36 (e.g., a flat flexible electrical cable) comprising an electrical contact 38. When the second electrical component 36 is an electrical cable, the electrical contact 38 can be an exposed portion or surface of an electrical conductor 46 of the electrical cable 36. The surface 38 can be exposed by removing a portion of the corresponding electrical insulation 48 encasing the conductor 46.

A second metal solder composition 40 having a second melting point is formed or otherwise disposed so as to function as an electrical connection between at least a portion of the electrical connection protrusion 34 and the electrical contact 38 of the second electrical component 36. The second melting point is lower than the first melting point, and there is a distinct interface of demarcation 42 between the electrical connection protrusion 34 and the second metal solder composition 40.

As shown in FIG. 2, the electrical connection protrusion 34 has an outer surface (see demarcation interface 42) that can be spaced apart from the electrical contact 38 of the second electrical component 36 such that the second metal solder composition 40 is disposed therebetween (i.e., between the outer surface of the electrical connection protrusion 34 and the electrical contact 38 of the second electrical component 36). Alternatively, the electrical contact 38 of the second electrical component 36 can be in direct contact (not shown) with a portion of the outer surface of the electrical connection protrusion 34 (see the point on the demarcation interface 42 closest to surface 38). In either case, the second metal solder composition 40 can be in a sufficient amount so as to be disposed around at least a portion of the outer surface of the electrical connection protrusion 34 so as to leave an outer exposed surface 50 of the electrical connection protrusion 34.

The first electrical component 32 includes an electrical contact 44 (e.g., a copper circuit board soldering pad), and the electrical connection protrusion 34 (e.g., in the form of a solder bump) is formed in electrical connection with the electrical contact 44 of the first electrical component 32. As illustrated in FIG. 2, the electrical connection protrusion 34 has a height extending straight down from and perpendicular to the plane of the contact 44 of the circuit board 32 and a longest dimension parallel to the plane of the contact 44 (i.e., perpendicular to the height). The electrical connection protrusion 34 can have a height in a range of from 0.25 mm to 2.5 mm, and a longest dimension perpendicular to the height in a range of from 0.5 mm to 5 mm. It can be desirable for the electrical connection protrusion 34 to have a longest dimension perpendicular to the height in a range from 1 mm to 4 mm. It can also be desirable for the longest dimension perpendicular to the height of the electrical connection protrusion 34 to be a diameter, and in particular for the protrusion 34 to have the shape of a hemisphere.

An electrical component assembly according to the present invention can be made by providing a first electrical component comprising an electrical contact; forming an electrical connection protrusion in electrical communication with the electrical contact of the first electrical component, with the electrical connection protrusion being made of a first metal solder composition having a first melting point; providing a second electrical component comprising an electrical contact; placing the electrical contact of the second electrical component and the electrical connection protrusion proximate to, and preferably so as to be in contact with, each other; disposing a second metal solder composition between at least a portion of the electrical connection protrusion and the electrical contact of the second electrical component, with the second metal solder composition having a second melting point that is lower than the first melting point; melting the second metal solder composition at a temperature below the first melting point so as to provide molten second metal solder composition between at least a portion of the electrical connection protrusion and the electrical contact of the second electrical component; and solidifying the molten second metal solder composition so as to form an electrical connection between at least a portion of the electrical connection protrusion and the electrical contact of the second electrical component. Preferably, the molten second metal solder composition is solidified such that there is a distinct interface of demarcation between the electrical connection protrusion and the second metal solder composition.

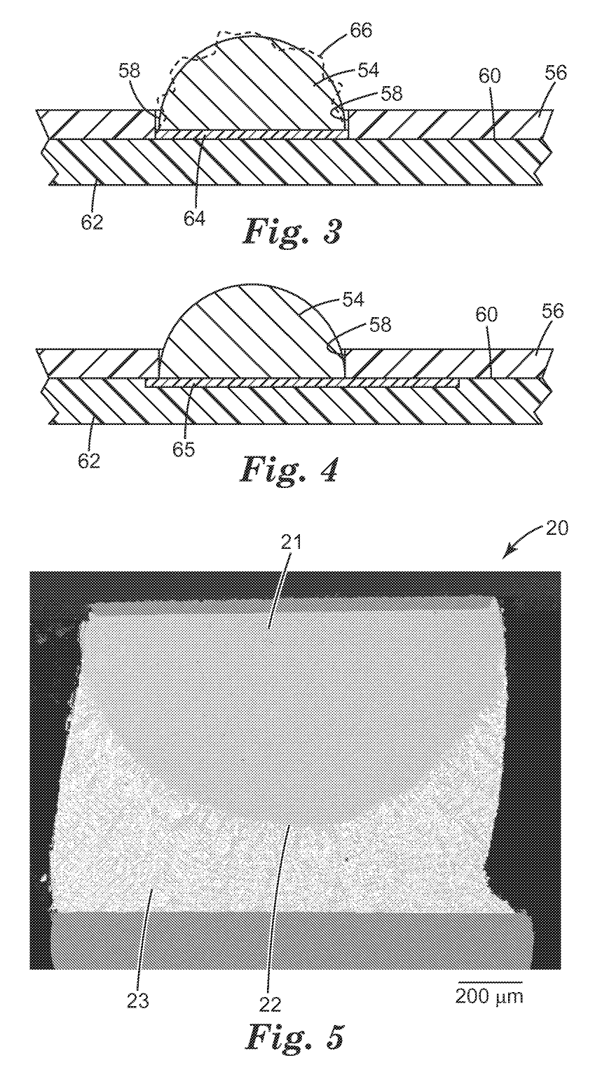

Referring to FIG. 3, an electrical connection protrusion 54 can be formed by: providing a solder mask 56 comprising at least one solder opening 58; disposing the solder mask 56 in proximity to, and preferably so as to contact, a surface 60 of the first electrical component 62 such that the electrical contact 64 of the first electrical component 62 is accessible through the solder opening 58; disposing an amount of first metal solder composition 66 (shown in phantom) through the solder opening 58 and onto the electrical contact 64 of the first electrical component 62. The amount of first metal solder composition 66 is then melted and the molten amount of solder composition 66 is solidified so as to form the electrical connection protrusion 54 in electrical connection with the electrical contact 64 of the first electrical component 62. The mask opening 58 can be configured so as to form a solder bump 54 having a height and a longest dimension perpendicular to the height. In the component 62 illustrated in FIG. 3, the electrical contact 64 is configured so as to extend above the first component surface 60 and dimensioned so as to be disposed completely within the confines of the solder opening 58. Alternatively, referring to FIG. 4, the first electrical component 62 can have an electrical contact 65 that is flush with the surface 60 of the first component 62 and that extends beyond the boundary set by the solder opening 58.

When the first electrical component 32 is a printed circuit board and the second electrical component 36 is an electrical cable comprising electrical insulation 48 disposed around an electrical conductor 46, the method can further comprise: removing a portion of the electrical insulation 48 (e.g., using conventional laser ablation techniques) so as to expose a portion of the electrical conductor 46, where the exposed portion of the electrical conductor 46 forms all or at least a portion of the electrical contact 38 of the second electrical component 36.

Suitable first and second metal compositions will be apparent to one skilled in the art reviewing the instant disclosure. Suitable compositions are typically provided as solders which are heated beyond their respective melting points to allow the material to flow for application to the desired surface(s). For example, an acceptable first or high temperature metal solder can be a Tin (Sn), Silver (Ag), Copper Cu) solder alloy (e.g., SAC305). In addition, an acceptable second or low temperature metal solder can be a Bismuth (BI) and Tin (Sn) solder from the Indium Corporation of America (Part No. 83464).

Further, one skilled in the art and reviewing the instant disclosure will be able to provide suitable electrical connection protrusion configurations, as well as the desired number and heights of the protrusions, and the solder masks and openings needed to obtain the desired protrusions. For example, an acceptable solder bump can have a height in the range of from 0.023″ to 0.035″ (584 to 889 μm) and a diameter of 0.050″ (1270 μm). A 0.020″ (508 μm) thick metal foil solder mask having a solder opening diameter of 0.054″ (1372 μm) can be used to form such a solder bump. The height of the protrusions facilitates providing the desired distance between the electrical components being electrically connected.

Embodiments of electrical component assemblies, and electrical component assemblies made as described herein, are useful for, and may be comprised in, task lighting and vehicles (e.g., automobiles, trucks, airplanes, trains, etc.). An exemplary vehicle electrical assembly is a brake center light.

Advantages and embodiments of this invention are further illustrated by the following examples, but the particular materials and amounts thereof recited in these examples, as well as other conditions and details, should not be construed to unduly limit this invention. All parts and percentages are by weight unless otherwise indicated.

### EXAMPLE

A lighting assembly was constructed as generally shown in FIGS. 1A-1D. A flat flexible cable was made by conventional techniques by drawing three rectangular copper conductors side-by-side through a pull-through die and encapsulating the three conductors with a TPE-E type insulation having a Shore D hardness of 72. The resulting flat flexible cable was 13.5 mm in width with the conductors arranged as shown in FIG. 1C. Two outer conductors (0.2 mm thick by 1.54 mm in width) were each located 0.9 mm from each edge of the cable. A center conductor (0.2 mm thick by 6.6 mm in width) was positioned between the two outer conductors with a separation of 1 mm from the two outer conductors. The total thickness of the cable was 0.55 mm.

A Class IV CO2 laser was used to make cut-outs and remove insulation from the flat flexible electrical cable, and thereby facilitating proper electrical contact for the resistors, LEDs and control circuits. A series of three electrically parallel groups of LEDs and control circuits were surface mounted onto the cable and electrically connected to the conductor below via the cut-outs. Each group consisted of four LED's (obtained under the trade designation “LCW W5AM” from Osram-Sylvania, Danvers, Mass.) followed by a control circuit. The control circuit consisted of the following components: an LED current regulator (obtained under the trade designation “A6260” from Allegro Microsystems, Worcester, Mass.), an associated sense resistor (obtained under the trade designation “0805”) for current level selection, a trim potentiometer, and a resistor to set the thermal monitor threshold where the output current starts to be reduced with increasing temperature.

The components were mounted onto an FR4 copper circuit board having 2 ounce copper. A maximum copper etch was utilized. The LEDs and control circuits were hand soldered to the cable using a conventional tin-lead solder paste. The circuit board with the control circuits and the flat flexible cable were electrically connected via solder bumps. Four tin-silver-copper solder bumps (1.3 mm (0.05 inch) diameter, 0.64 mm (0.025 inch) height) made of solder obtained under the trade designation “NC254” from Aim Solder, Cranston, R.I.) were provided on the control circuits. These solder bumps had exposed outer surfaces. The electrical contacts of the flat flex cable were placed in direct contact with a portion of the respective outer exposed surfaces of the solder bumps, leaving a remaining outer exposed surface of the solder bump. A second, bismuth-tin solder (made of solder obtained under the trade designation “INDALLOY #281” from Indium Corporation of America, Utica, N.Y.) was heated to provide a melt that was disposed around the remaining exposed outer surface of the solder bump without melting the first solder, and then cooled.

The first group was constructed with a Schottky diode (obtained under the trade designation “MBRS360T3G” from ON Semiconductor, Phoenix, Ariz.) positioned to bridge the outer conductor (power supply) and the center conductor of the cable. The first LED within a group was positioned with its anode electrically connected to the Schottky diode. The second, third and fourth LEDs were positioned with their anodes biased to the higher potential. The control circuit was positioned on the cable such that it was electrically connected to the cathode of the fourth LED. The control circuit regulates the current in a group and provides the power connection (bridge) from the power conductor to the anode of the first LED in the next group via the center conductor, and bridges from the center conductor and the outer conductor (ground potential).

The spacing between the first resistor and first LED in the first group was about 100 mm. The spacing between each LED within a group was about 110 mm. The spacing between the last LED in the group and the control circuit was about 60 mm. The spacing between the control circuit and the first LED in the next group was about 100 mm. An additional cut-out was made through the center conductor using a conventional punch tool in a hand operated press, in between each group to interrupt electrical current flow and provide series-parallel electrical circuits in the flat flexible cable. To provide power to the lighting assembly, one of the outer conductors was connected to a positive power supply potential and the other outer conductor was connected to a ground potential.

One of the electrical protrusions was cut out of the assembly with a band saw and then further cut to a size of about 1.9 cm (0.75 inch) using a diamond saw (obtained under the trade designation “STRUER'S ACCUTOM-50” from Struers Inc, Westlake, Ohio). The sample was then positioned in 2.5 cm (1.25 inch 1.0 inch?—confirm!) phenolic rings using plastic clips with the writing side facing the puck label (mounting products obtained from Buehler Ltd., Lake Bluff, Ill.). The sample was then placed in a vacuum chamber and mounted in epoxy (obtained under the trade designation “EPDXICURE” from Buehler Ltd.) under vacuum. The epoxy was allowed to cure overnight, and the sample was then polished using conventional techniques using 320 grit grinding paper with water and conventional lubricant, followed by 600 grit grinding paper with water and conventional lubricant, followed by sequentially, 9 micrometer diamond suspension with conventional lubricant, 3 micrometer diamond suspension with conventional lubricant, and 1 micrometer diamond suspension with water (polishing products obtained from Buehler Ltd., Lake Bluff, Ill., including polishing materials obtained under the trade designation “METADI”).

The polished sample was then examined using a scanning electron microscope (obtained under the trade designation “FEI XL30 ENVIRONMENTAL SCANNING ELECTRON MICROSCOPE” from FEI Company, Hillsboro, Oreg.) operating in high vacuum mode. A 75× backscattered electron imaging (BSEI) of the polished sample (20) is show in FIG. 5 having a distinct interface of demarcation 22 between electrical connection protrusion 21 and solder 23.

### Additional Embodiments

1. An electrical component assembly comprising: a first electrical component having an electrical connection protrusion, the electrical connection protrusion made of a first metal composition having a first melting point, the electrical connection protrusion having an exposed outer surface, a height in a range from 0.25 mm to 2.5 mm, and a longest dimension perpendicular to the height in a range from 0.5 mm to 5 mm; a second electrical component electrical contact in direct contact with a portion of the outer exposed surface of the electrical connection protrusion, leaving a remaining outer exposed surface of the electrical connection protrusion; and a second metal composition having a second melting point, lower than the first melting point, the second metal composition being disposed around the remaining exposed outer surface of the electrical connection protrusion, wherein there is a distinct line of demarcation between the electrical connection protrusion and the second metal composition.

2. The electrical component assembly according to embodiment 1, wherein the electrical connection protrusion is a solder bump.

3. The electrical component assembly according to either embodiment 1 or 2, wherein the electrical connection protrusion has a longest dimension perpendicular to the height in a range from 1 mm to 4 mm.

4. The electrical component assembly according to any preceding embodiment, wherein the longest dimension perpendicular to the height is a diameter.

5. The electrical component assembly according to any preceding embodiment, wherein the first electrical component is a printed circuit board.

6. The electrical component assembly according to any preceding embodiment, wherein the second electrical component is a flexible cable.

7. A vehicle comprising the electrical component assembly according to any preceding electrical component assembly embodiment.

8. The vehicle according to embodiment 7, wherein the lighting assembly is a brake center light.

9. The vehicle according to any of embodiments 7 or 8, which is an automobile.

10. The vehicle according to any of embodiments 7 to 9, which is a truck.

11. The flexible lighting assembly comprising any preceding electrical component assembly embodiment (e.g., task lighting).

12. A method of making an electrical component assembly comprising: providing a first electrical component having an electrical connection protrusion, the electrical connection protrusion made of a first metal composition having a first melting point, the electrical connection protrusion having an exposed outer surface, a height in a range from 0.25 mm to 2.5 mm, and a longest dimension perpendicular to the height in a range from 0.5 mm to 5 mm; providing a second electrical component electrical contact; placing the electrical contact in direct contact with a portion of the outer exposed surface of the electrical connection protrusion, leaving a remaining outer exposed surface of the electrical connection protrusion; providing a second solder composition having a second melting point, lower than the first melting point; heating the second solder composition to provide a melt that is disposed around at least a portion of the remaining exposed outer surface of the electrical connection protrusion without melting the first metal composition; and cooling the melt disposed around at least a portion of the remaining exposed outer surface of the electrical connection protrusion.

13. The method according to any preceding method embodiment, wherein the electrical connection protrusion is a solder bump.

14. The method according to any preceding method embodiment, wherein the electrical connection protrusion has a longest dimension perpendicular to the height in a range from 1 mm to 4 mm.

15. The electrical component assembly according to any preceding method embodiment, wherein the longest dimension perpendicular to the height is a diameter.

16. The method according to any preceding method embodiment, wherein the first electrical component is a printed circuit board.

17. The method according to any preceding method embodiment, wherein the second electrical component is a flexible electrical cable.

Foreseeable modifications and alterations of this invention will be apparent to those skilled in the art without departing from the scope and spirit of this invention. This invention should not be restricted to the embodiments that are set forth in this application for illustrative purposes.

1. An electrical component assembly comprising:
a first electrical component comprising an electrical connection protrusion being made of a first metal solder composition having a first melting point, with said second electrical component being a flexible cable comprising an electrical conductor, and the electrical contact of said second electrical component being an exposed portion of the electrical conductor of said flexible cable;
a second electrical component comprising an electrical contact; and
a second metal solder composition having a second melting point and being disposed so as to function as an electrical connection between at least a portion of said electrical connection protrusion and the electrical contact of said second electrical component,
wherein the second melting point is lower than the first melting point, and there is a distinct interface of demarcation between said electrical connection protrusion and said second metal solder composition.

2. The electrical component assembly according to claim 1, wherein said first electrical component further comprises an electrical contact, said electrical connection protrusion is a solder bump formed so as to be in electrical connection with the electrical contact of said first electrical component, and said solder bump has a height and a longest dimension perpendicular to the height.

3. The electrical component assembly according to claim 1, wherein said electrical connection protrusion has a height in a range from 0.25 mm to 2.5 mm, and a longest dimension perpendicular to the height in a range from 0.5 mm to 5 mm.

4. The electrical component assembly according to claim 1, wherein said first electrical component is a printed circuit board.

5. (canceled)

6. The electrical component assembly according to claim 1, wherein said electrical connection protrusion has an outer surface that is spaced apart from the electrical contact of said second electrical component such that said second metal solder composition is disposed therebetween.

7. The electrical component assembly according to claim 1, wherein said electrical connection protrusion has an outer surface that is spaced apart from the electrical contact of said second electrical component such that said second metal solder composition is disposed therebetween and around at least a portion of the outer surface of said electrical connection protrusion so as to leave an outer exposed surface of said electrical connection protrusion.

8. The electrical component assembly according to claim 1, wherein said electrical connection protrusion has an outer surface, the electrical contact of said second electrical component is in direct contact with a portion of the outer surface of said electrical connection protrusion, said second metal solder composition is disposed around at least a portion of the outer surface of said electrical connection protrusion so as to leave an outer exposed surface of said electrical connection protrusion.

9. A flexible lighting assembly comprising said electrical component assembly according to any claim 1.

10. The flexible lighting assembly according to claim 9, wherein said first electrical component is circuit board, said second electrical component is a flat flexible cable, and the electrical contact of said second electrical component is an exposed surface of an electrical conductor of said flat flexible cable.

11. A method of making an electrical component assembly according to claim 10, said method comprising:
providing a first electrical component comprising an electrical contact, wherein the first electrical component is a printed circuit board;
forming an electrical connection protrusion in electrical communication with the electrical contact of the first electrical component, with the electrical connection protrusion being made of a first metal solder composition having a first melting point;
providing a second electrical component comprising an electrical contact, with the second electrical component being a flexible cable comprising electrical insulation disposed around an electrical conductor;
removing a portion of the electrical insulation so as to expose a portion of the electrical conductor, where the exposed portion of the electrical conductor forms the electrical contact of the second electrical component;
placing the electrical contact of the second electrical component and the electrical connection protrusion proximate to each other;
disposing a second metal solder composition between at least a portion of the electrical connection protrusion and the electrical contact of the second electrical component, with the second metal solder composition having a second melting point that is lower than the first melting point;
melting the second metal solder composition at a temperature below the first melting point so as to provide molten second metal solder composition between at least a portion of the electrical connection protrusion and the electrical contact of the second electrical component; and
solidifying the molten second metal solder composition so as to form an electrical connection between at least a portion of said electrical connection protrusion and the electrical contact of said second electrical component.

12. The method according to claim 11, wherein the molten second metal solder composition is solidified such that there is a distinct interface of demarcation between the electrical connection protrusion and the second metal solder composition.

13. The method according to claim 11, wherein said forming the electrical connection protrusion comprises:
providing a solder mask comprising a solder opening;
disposing the solder mask in proximity to the first electrical component such that the electrical contact of the first electrical component is accessible through the solder opening;
disposing an amount of first metal solder composition through the solder opening and onto the electrical contact of the first electrical component;
melting the amount of first metal solder composition; and
solidifying the molten amount of first metal solder composition so as to form the electrical connection protrusion in electrical connection with the electrical contact of the first electrical component.

14. The method according to claim 13, wherein the mask opening is configured so as to form a solder bump, and the electrical connection protrusion is a solder bump having a height and a longest dimension perpendicular to the height.

15. (canceled)

16. The electrical component assembly according to claim 2, wherein said electrical connection protrusion has a height in a range from 0.25 mm to 2.5 mm, and a longest dimension perpendicular to the height in a range from 0.5 mm to 5 mm.

17. The electrical component assembly according to claim 2, wherein said first electrical component is a printed circuit board.

18. The electrical component assembly according to claim 3, wherein said first electrical component is a printed circuit board.

19. The electrical component assembly according to claim 4, wherein said electrical connection protrusion has an outer surface that is spaced apart from the electrical contact of said second electrical component such that said second metal solder composition is disposed therebetween.

20. The electrical component assembly according to claim 4, wherein said electrical connection protrusion has an outer surface that is spaced apart from the electrical contact of said second electrical component such that said second metal solder composition is disposed therebetween and around at least a portion of the outer surface of said electrical connection protrusion so as to leave an outer exposed surface of said electrical connection protrusion.

21. The electrical component assembly according to claim 4, wherein said electrical connection protrusion has an outer surface, the electrical contact of said second electrical component is in direct contact with a portion of the outer surface of said electrical connection protrusion, said second metal solder composition is disposed around at least a portion of the outer surface of said electrical connection protrusion so as to leave an outer exposed surface of said electrical connection protrusion.

22. The electrical component assembly according to claim 1, wherein said first electrical component further comprises an electrical contact, said electrical connection protrusion is a solder bump formed so as to be in electrical connection with the electrical contact of said first electrical component, said solder bump has a height and a longest dimension perpendicular to the height, said electrical connection protrusion has a height in a range from 0.25 mm to 2.5 mm, a longest dimension perpendicular to the height in a range from 0.5 mm to 5 mm, said first electrical component is a printed circuit board, said electrical connection protrusion has an outer surface that is spaced apart from the electrical contact of said second electrical component such that said second metal solder composition is disposed therebetween, and wherein either (a) said electrical connection protrusion has an outer surface that is spaced apart from the electrical contact of said second electrical component such that said second metal solder composition is disposed therebetween and around at least a portion of the outer surface of said electrical connection protrusion so as to leave an outer exposed surface of said electrical connection protrusion, or (b) said electrical connection protrusion has an outer surface, the electrical contact of said second electrical component is in direct contact with a portion of the outer surface of said electrical connection protrusion, said second metal solder composition is disposed around at least a portion of the outer surface of said electrical connection protrusion so as to leave an outer exposed surface of said electrical connection protrusion.
